(19) United States
(12) Patent Application Publication
(10) Pub. No.: US 2019/0378696 A1
(43) Pub. Date: Dec. 12, 2019

(54) APPARATUS FOR SUPPRESSING PARASITIC PLASMA IN PLASMA ENHANCED CHEMICAL VAPOR DEPOSITION CHAMBER

(71) Applicant: Applied Materials, Inc., Santa Clara, CA (US)

(72) Inventors: Sai Susmita ADDEPALLI, San Jose, CA (US); Satish KATAMBLI, Hungund (IN); Mayur Govind KULKARNI, Bangalore (IN); Hanish Kumar PANAVALAPPIL KUMARANKUTTY, Bangalore (IN); Vinay K. PRABHAKAR, Cupertino, CA (US); Edward P. HAMMOND, IV, Hillsborough, CA (US); Juan Carlos ROCHA, San Carlos, CA (US)

(21) Appl. No.: 16/429,368

(22) Filed: Jun. 3, 2019

Related U.S. Application Data
(60) Provisional application No. 62/682,557, filed on Jun. 8, 2018.

(51) Int. Cl. H01J 37/32; C23C 16/50; C23C 16/46; C23C 16/458

(52) U.S. Cl. CPC H01J 37/32651; H01J 37/32724; H01J 37/3244; H01J 2237/3321; C23C 16/46; C23C 16/4586; H01J 2237/002; C23C 16/50

(57) ABSTRACT

Embodiments of the present disclosure generally relate to a metal shield to be used in a PECVD chamber. The metal shield includes a substrate support portion and a shaft portion. The shaft portion includes a tubular wall having a wall thickness. The tubular wall has a supply channel of a coolant channel and a return channel of the coolant channel embedded therein. Each of the supply channel and the return channel is a helix in the tubular wall. The helical supply channel and the helical return channel have the same direction of rotation and are parallel to each other. The supply channel and the return channel are interleaved in the tubular wall. With the supply channel and return channel interleaved in the metal shield, the thermal gradient in the metal shield is reduced.

### CROSS-REFERENCE TO RELATED APPLICATIONS

This application claims priority to U.S. Provisional Patent Application Ser. No. 62/682,557, filed on Jun. 8, 2018, which herein is incorporated by reference.

### FIELD

Embodiments of the present disclosure generally relate to process chambers, such as plasma enhanced chemical vapor deposition (PECVD) chambers. More particularly, embodiments of the present disclosure relate to a substrate support assembly disposed in a PECVD chamber.

### BACKGROUND

### Description of the Related Art

Plasma enhanced chemical vapor deposition (PECVD) is used to deposit thin films on a substrate, such as a semiconductor wafer or a transparent substrate. PECVD is generally accomplished by introducing a precursor gas or gas mixture into a vacuum chamber containing a substrate disposed on a substrate support. The precursor gas or gas mixture is typically directed downwardly through a gas distribution plate situated near the top of the chamber. The precursor gas or gas mixture in the chamber is energized (e.g., excited) into a plasma by applying a power, such as a radio frequency (RF) power, to an electrode in the chamber from one or more power sources coupled to the electrode. The excited gas or gas mixture reacts to form a layer of material on a surface of the substrate. The layer may be, for example, a passivation layer, a gate insulator, a buffer layer, and/or an etch stop layer.

During PECVD, a capacitively coupled plasma, also known as a main plasma, is formed between the substrate support and the gas distribution plate. However, a parasitic plasma, also known as a secondary plasma, may be generated underneath the substrate support in a lower volume of the chamber. The parasitic plasma reduces the concentration of the capacitive coupled plasma, and thus reduces the density of the capacitive coupled plasma which reduces the deposition rate of the film. Furthermore, variation of the concentration and density of the parasitic plasma between chambers reduces the uniformity between films formed in separate chambers.

Accordingly, an improved substrate support assembly is needed to mitigate the generation of parasitic plasma.

### SUMMARY

Embodiments of the present disclosure generally relate to a metal shield to be used in a PECVD chamber. In one embodiment, a metal shield includes a metal plate, a metal hollow tube including a tubular wall, and a coolant channel formed in the metal plate and tubular wall of the metal hollow tube. The coolant channel includes a supply channel having a planar spiral pattern in the metal plate and a helical pattern in the tubular wall of the metal hollow tube. The coolant channel further includes a return channel having a planar spiral pattern in the metal plate and a helical pattern in the tubular wall of the metal hollow tube. The supply channel and the return channel are interleaved in the metal plate and the tubular wall.

In another embodiment, a substrate support assembly includes a heater plate, a thermal insulating plate having a surface facing the heater plate, and a first plurality of reduced contact features formed on the surface of the thermal insulating plate. The heater plate is in contact with the first plurality of reduced contact features. The substrate support assembly further includes a metal shield including a metal plate and a metal hollow tube having a metal tubular wall. The metal plate includes a surface facing the thermal insulating plate, and a second plurality of reduced contact features is formed on the surface of the metal plate. The thermal insulating plate is in contact with the second plurality of reduced contact features.

In another embodiment, a process chamber includes a chamber wall, a bottom, a gas distribution plate, and a substrate support assembly. The substrate support assembly includes a heater plate, a thermal insulating plate having a surface facing the heater plate, and a first plurality of reduced contact features formed on the surface of the thermal insulating plate. The heater plate is in contact with the first plurality of reduced contact features. The substrate support assembly further includes a metal shield including a metal plate and a metal hollow tube having a metal tubular wall. The metal plate includes a surface facing the thermal insulating plate, and a second plurality of reduced contact features is formed on the surface of the metal plate. The thermal insulating plate is in contact with the second plurality of reduced contact features.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a process chamber including a substrate support assembly according to one embodiment.

FIG. 2A is schematic cross-sectional view of the substrate support assembly of FIG. 1.

FIG. 2B is a schematic cross-sectional view of a portion of a metal shield of the substrate support assembly of FIG. 1.

FIG. 3A is a top view of a thermal insulating plate of the substrate support assembly of FIG. 1.

FIG. 3B is a bottom view of the thermal insulating plate of the substrate support assembly of FIG. 1.

FIG. 4 is a perspective view of the metal shield of the substrate support assembly of FIG. 1.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a metal shield to be used in a PECVD chamber. The metal shield includes a substrate support portion and a shaft portion. The shaft portion includes a tubular wall having a wall thickness. The tubular wall has a supply channel of a coolant channel and a return channel of the coolant channel embedded therein. Each of the supply channel and the return channel is a helix in the tubular wall. The helical supply channel and the helical return channel have the same direction of rotation and are parallel to each other. The supply channel and the return channel are interleaved in the tubular wall. With the supply channel and return channel interleaved in the metal shield, the thermal gradient in the metal shield is reduced.

Embodiments herein are illustratively described below in reference to use in a PECVD system configured to process substrates, such as a PECVD system, available from Applied Materials, Inc., Santa Clara, Calif. However, it should be understood that the disclosed subject matter has utility in other system configurations such as etch systems, other chemical vapor deposition systems, and any other system in which a substrate is exposed to plasma within a process chamber. It should further be understood that embodiments disclosed herein may be practiced using process chambers provided by other manufacturers and chambers using multiple shaped substrates. It should also be understood that embodiments disclosed herein may be adapted for practice in other process chambers configured to process substrates of various sized and dimensions.

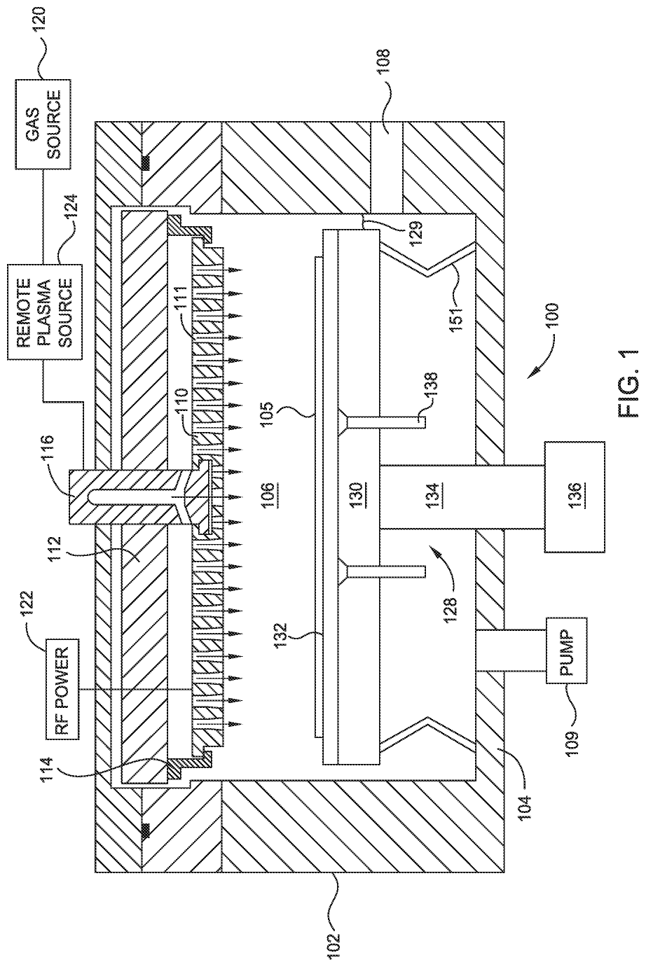

FIG. 1 is a schematic cross-sectional view of a process chamber 100 including a substrate support assembly 128 according to one embodiment described herein. In the example of FIG. 1, the process chamber 100 is a PECVD chamber. As shown in FIG. 1, the process chamber 100 includes one or more walls 102, a bottom 104, a gas distribution plate 110, and the substrate support assembly 128. The walls 102, bottom 104, gas distribution plate 110, and substrate support assembly 128 collectively define a processing volume 106. The processing volume 106 is accessed through a sealable slit valve opening 108 formed through the walls 102 such that a substrate 105 may be transferred in and out of the process chamber 100.

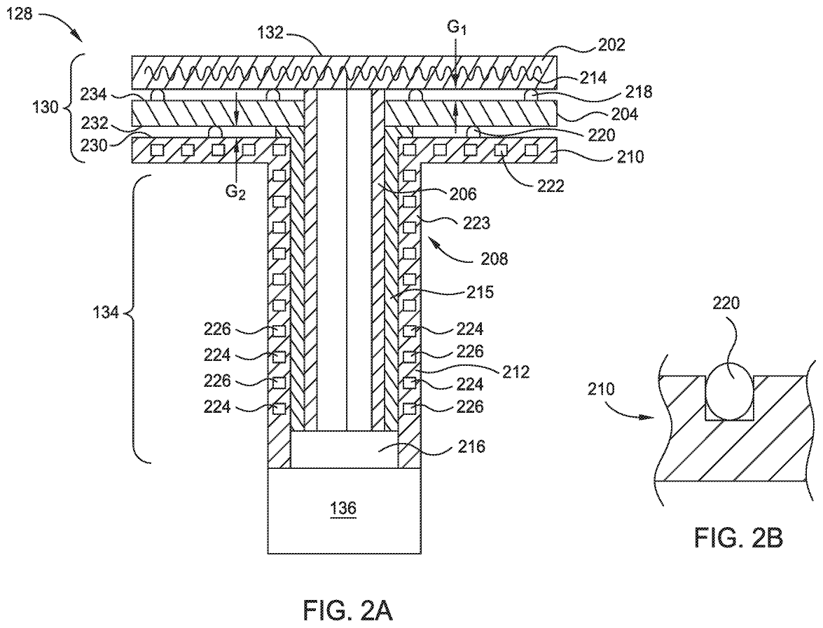

The substrate support assembly 128 includes a substrate support portion 130 and a shaft portion 134. The shaft portion 134 is coupled to a lift system 136 that is adapted to raise and lower the substrate support assembly 128. The substrate support portion 130 includes a substrate receiving surface 132 for supporting the substrate 105. Lift pins 138 are moveably disposed through the substrate support portion 130 to move the substrate 105 to and from the substrate receiving surface 132 to facilitate substrate transfer. The substrate support portion 130 may also include grounding straps 129 or 151 to provide RF grounding at the periphery of the substrate support portion 130. The substrate support assembly 128 is described in detail in FIGS. 2A-2C.

In one embodiment, the gas distribution plate 110 is coupled to a backing plate 112 at the periphery by a suspension 114. In other embodiments, the backing plate 112 is not present, and the gas distribution plate 110 is coupled to the walls 102. A gas source 120 is coupled to the backing plate 112 (or the gas distribution plate) through an inlet port 116. The gas source 120 may provide one or more gases through a plurality of gas passages 111 formed in the gas distribution plate 110 and to the processing volume 106. Suitable gases may include, but are not limited to, a silicon-containing gas, a nitrogen-containing gas, an oxygen-containing gas, an inert gas, or other gases.

A vacuum pump 109 is coupled to the process chamber 100 to control the pressure within the processing volume 106. An RF power source 122 is coupled to the backing plate 112 and/or directly to the gas distribution plate 110 to provide RF power to the gas distribution plate 110. The RF power source 122 may generate an electric field between the gas distribution plate 110 and the substrate support assembly 128. The electric field may form a plasma from the gases present between the gas distribution plate 110 and the substrate support assembly 128. Various RF frequencies may be used. For example, the frequency may be between about 0.3 MHz and about 200 MHz, such as about 13.56 MHz.

A remote plasma source 124, such as an inductively coupled remote plasma source, may also be coupled between the gas source 120 and the inlet port 116. Between processing substrates, a cleaning gas may be provided to the remote plasma source 124. The cleaning gas may be excited to a plasma within the remote plasma source 124, forming a remote plasma. The excited species generated by the remote plasma source 124 may be provided into the process chamber 100 to clean chamber components. The cleaning gas may be further excited by the RF power source 122 reduce recombination of the dissociated cleaning gas species. Suitable cleaning gases include but are not limited to NF₃, F₂, and SF₆.

The chamber 100 may be used to deposit a material, such as a silicon-containing material. For example, the chamber 100 may be used to deposit one or more layers of amorphous silicon (a—Si), silicon nitride (SiNₓ), and/or silicon oxide (SiOₓ).

FIG. 2A is schematic cross-sectional view of the substrate support assembly 128 of FIG. 1 according to one embodiment described herein. As shown in FIG. 2A, the substrate support assembly 128 includes the substrate support portion 130 and the shaft portion 134. The substrate support portion 130 includes a heater plate 202 and a thermal insulating plate 204. The heater plate 202 may be fabricated from a ceramic material, such as aluminum oxide or aluminum nitride. In one embodiment, the heater plate 202 is fabricated from anodized aluminum. A heating element 214 is embedded in the heater plate 202 for heating the substrate 105 (as shown in FIG. 1) disposed thereon to a predetermined temperature during operation. In one embodiment, the substrate 105 (as shown in FIG. 1) is heated by the heater plate 202 to a temperature over 500 degrees Celsius during operation. The thermal insulating plate 204 is fabricated from a ceramic material, such as aluminum oxide or aluminum nitride. In one embodiment, the thermal insulating plate 204 is fabricated from aluminum oxide. The shaft portion 134 includes a stem 206 connected to the heater plate 202. The stem 206 is a hollow tube and may be fabricated from the same material as the heater plate 202.

In one embodiment, the stem 206 and the heater plate 202 are fabricated from a single piece of material. The stem 206 is connected to a connector 216, which is in turn connected to the lift system 136.

The substrate support assembly 128 further includes a metal shield 208. The metal shield 208 includes a substrate support portion 210 supported by a shaft portion 212. The substrate support portion 210 is part of the substrate support portion 130 of the substrate support assembly 128, and the shaft portion 212 is part of the shaft portion 134 of the substrate support assembly 128. In one embodiment, the substrate support portion 210 of the metal shield 208 is a metal plate, and the shaft portion 212 of the metal shield 208 is a metal hollow tube. The substrate support portion 210 and the shaft portion 212 of the metal shield 208 are fabricated from a metal, such as aluminum, molybdenum, titanium, beryllium, copper, stainless steel, or nickel. In one embodiment, the substrate support portion 210 and the shaft portion 212 of the metal shield 208 are fabricated from aluminum, because aluminum is not eroded by the cleaning species, such as fluorine containing species. In another embodiment, the substrate support portion 210 is fabricated from stainless steel. In one embodiment, the substrate support portion 210 and the shaft portion 212 of the metal shield 208 are separate components that are connected by any suitable connecting method. In another embodiment, the substrate support portion 210 and the shaft portion 212 of the metal shield 208 are a single piece of material.

The metal shield 208 is grounded via the grounding straps 129 or 151 during a PECVD process. The grounded metal shield 208 functions as an RF shield that can substantially reduce the generation of parasitic plasma. In one embodiment, the metal shield 208 is fabricated from aluminum, because aluminum does not contribute to metal contamination and is resistive to the fluorine containing species formed during the cleaning process. However, mechanical and electrical properties of the metal shield 208 fabricated from aluminum can degrade at processing temperatures greater than 500 degrees Celsius. Thus, in applications when the metal shield 208 is intended for use at temperatures near or exceeding 500 degrees Celsius, the metal shield 208 includes cooling elements, such as a coolant channel 222 is formed in the metal shield 208.

The shaft portion 212 of the metal shield 208 includes a tubular wall 223, and the coolant channel 222 is formed in the tubular wall 223 and the substrate support portion 210. The coolant channel 222 includes a supply channel 224 and a return channel 226. Each of the supply channel 224 and the return channel 226 is a helix in the tubular wall 223. The helical supply channel 224 and the helical return channel 226 formed in the tubular wall 223 have the same direction of rotation and are parallel to each other. The helical supply channel 224 and the helical return channel 226 are alternately positioned in the tubular wall 223. In other words, the helical supply channel 224 and the helical return channel 226 are interleaved in the tubular wall 223. The supply channel 224 and the return channel 226 formed in the substrate support portion 210 have planar spiral patterns, and the spiral supply channel 224 and the spiral return channel 226 are alternately positioned in the substrate support portion 210. In other words, the spiral supply channel 224 and the spiral return channel 226 are interleaved in the substrate support portion 210. With the supply channel 224 and return channel 226 positioned alternately, or interleaved, in the metal shield 208, the thermal gradient in the metal shield 208 is reduced.

The thermal insulating plate 204 is disposed between the heater plate 202 and the substrate support portion 210 of the metal shield 208 to keep the metal shield 208 at a lower temperature than the heater plate 202 during operation. In addition, a thermal insulating tube 215 is disposed between the stem 206 and the shaft portion 212 of the metal shield 208 to reduce heat transfer from the stem 206 to the shaft portion 212 of the metal shield 208. Furthermore, reduced contact features 218, 220 are utilized at the interface between the heater plate 202 and the thermal insulating plate 204 and at the interface between the thermal insulating plate 204 and the substrate support portion 210 of the metal shield 208, respectively. The reduced contact features 218, 220 limit contact and thus limit thermal conductive heat transfer from the heater plate 202 to the metal shield 208 during operation. The reduced contact feature 218 extends from a surface 234 of the thermal insulating plate 204, and the surface 234 faces the heater plate 202. The thermal insulating plate 204 has a surface 232 opposite the surface 234. The reduced contact feature 220 is disposed on or in a surface 230 of the substrate support portion 210 of the metal shield 208, and the surface 230 faces the thermal insulating plate 204. The heater plate 202 is in contact with the reduced contact feature 218, and a gap G1 is formed between the heater plate 202 and the surface 234 of the thermal insulating plate 204. The thermal insulating plate 204 is in contact with the reduced contact feature 220, and a gap G2 is formed between the surface 232 of the thermal insulating plate 204 and the surface 230 of the substrate support portion 210 of the metal shield 208.

FIG. 2B is a schematic cross-sectional view of a portion of the metal shield 208 of the substrate support assembly 128 of FIG. 1 according to one embodiment described herein. As shown in FIG. 2B, the reduced contact feature 220 is a ball that is partially embedded in the substrate support portion 210 of the metal shield 208. The reduced contact feature 220 may be fabricated from a thermally insulating material, such as sapphire. The number and the pattern of the reduced contact features 220 are determined to provide reduced heat loss from the heater plate 202. In one embodiment, three reduced contact features 220 are utilized, and the three reduced contact features 220 are patterned to form an equilateral triangle. The reduced contact feature 220 may have a shape other than spherical, such as pyramidal, cylindrical, or conical.

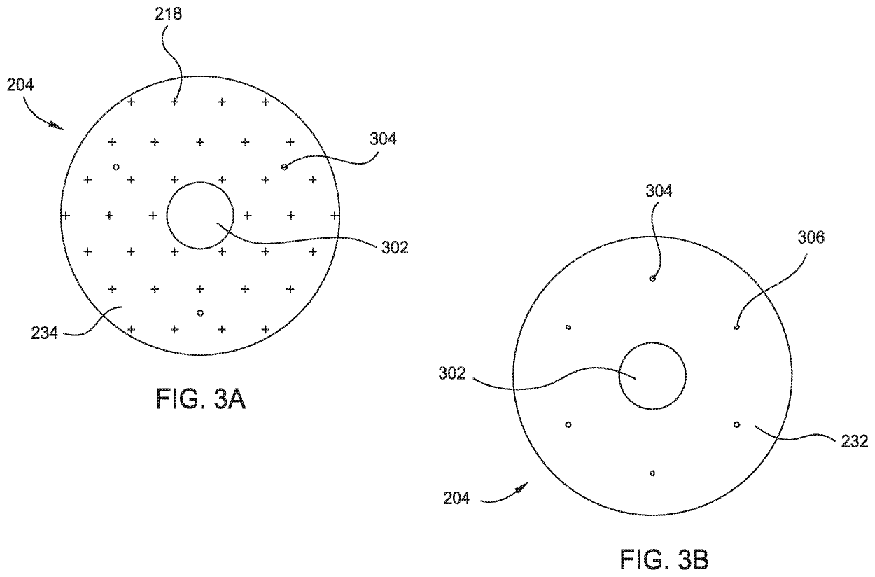

FIG. 3A is a top view of the thermal insulating plate 204 of the substrate support assembly 128 of FIG. 1 according to one embodiment described herein. As shown in FIG. 3A, the thermal insulating plate 204 includes an opening 302 for the stem 206 (as shown in FIG. 2A) to extend therethrough. The thermal insulating plate 204 further includes a plurality of lift pin holes 304 for the lift pins 138 to extend therethrough. The plurality of reduced contact features 218 are formed extending from the surface 234 of the thermal insulating plate 204. The reduced contact features 218 may be fabricated from a thermally insulating material, such as a ceramic material, for example aluminum oxide or aluminum nitride. In one embodiment, the reduced contact features 218 are protrusions formed on the surface 234 of the thermal insulating plate 204. The protrusions may have any suitable shape, such as spherical, cylindrical, pyramidal, or conical. In one embodiment, each protrusion is cylindrical. In one example, the height of each reduced contact feature 218 extending from the surface 234 is the same as the gap G1. The number and the pattern of the reduced contact features 218 are selected to provide reduced heat loss from the heater plate 202. In one embodiment, as shown in FIG. 3A, the reduced contact features 218 have a honey comb pattern. The number of the reduced contact features 218 formed in or on the surface 234 of the thermal insulating plate 204 ranges from about 30 to about 120, or as otherwise desired.

FIG. 3B is a bottom view of the thermal insulating plate 204 of the substrate support assembly 128 of FIG. 1 according to one embodiment described herein. As shown in FIG. 3B, the thermal insulating plate 204 includes the opening 302 and the lift pin holes 304. A plurality of recesses 306 is formed in the surface 232 of the thermal insulating plate 204. The recesses 306 are positioned to receive corresponding minimum contact features 220 formed in or on the substrate support portion 210 of the metal shield 208. Thus, the number and pattern of the recesses 306 are the same as the number and pattern of the minimum contact features 220.

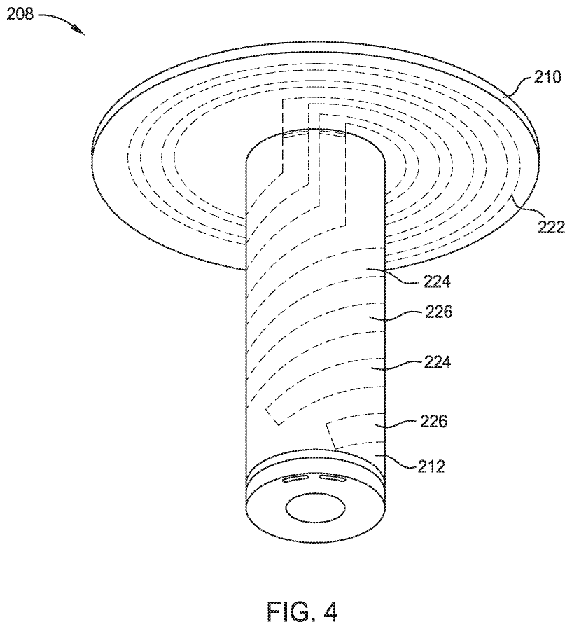

FIG. 4 is a perspective view of the metal shield 208 of the substrate support assembly 128 of FIG. 1 according to one embodiment described herein. As shown in FIG. 4, the metal shield 208 includes the substrate support portion 210, or a metal plate, and the shaft portion 212, or a metal hollow tube, coupled to the substrate support portion 210. The metal shield 208 includes the coolant channel 222 formed therein. The coolant channel 222 includes the supply channel 224 and the return channel 226. The supply channel 224 has a planar spiral pattern in the substrate support portion 210 and a helical pattern in the shaft portion 212. Similarly, the return channel 226 has a planar spiral pattern in the substrate support portion 210 and a helical pattern in the shaft portion 212.

During operation, a coolant, such as water, ethylene glycol, perfluoropolyether fluorinated fluid, or combinations thereof, flows from the supply channel 224 to the return channel 226. The return channel 226 is fluidly connected to the supply channel 224 at a location in the substrate support portion 210. The supply channel 224 is substantially parallel to the return channel 226 in the substrate support portion 210 and the shaft portion 212. Furthermore, the helical supply channel 224 and the helical return channel 226 formed in the shaft portion 212 have the same direction of rotation. The helical supply channel 224 and the helical return channel 226 are interleaved in the shaft portion 212, and the spiral supply channel 224 and the spiral return channel 226 are interleaved in the substrate support portion 210. With the supply channel 224 and return channel 226 interleaved in the metal shield 208, the thermal gradient in the metal shield 208 is reduced.

While the foregoing is directed to embodiments of the present disclosure, other and further embodiments of the disclosure may be devised without departing from the basic scope thereof, and the scope thereof is determined by the claims that follow.

What is claimed is:

1. A metal shield, comprising:
a metal plate;
a metal hollow tube comprising a tubular wall; and
a coolant channel formed in the metal plate and tubular wall of the metal hollow tube, the coolant channel comprising:
a supply channel having a planar spiral pattern in the metal plate and a helical pattern in the tubular wall of the metal hollow tube; and
a return channel having a planar spiral pattern in the metal plate and a helical pattern in the tubular wall of the metal hollow tube, the supply channel and the return channel being interleaved in the metal plate and the tubular wall.

2. The metal shield of claim 1, wherein the metal shield is fabricated from aluminum, molybdenum, titanium, beryllium, copper, stainless steel, or nickel.

3. The metal shield of claim 2, wherein the metal shield is fabricated from aluminum.

4. The metal shield of claim 1, wherein the metal plate and the metal hollow tube are a single piece of material.

5. The metal shield of claim 1, further comprising a plurality of minimum contact features formed in a surface of the metal plate.

6. The metal shield of claim 5, wherein the plurality of minimum contact features comprises a plurality of sapphire balls partially embedded in the metal plate.

7. A substrate support assembly, comprising:
a heater plate;
a thermal insulating plate having a surface facing the heater plate;
a first plurality of reduced contact features formed on the surface of the thermal insulating plate, the heater plate being in contact with the first plurality of reduced contact features;
a metal shield comprising a metal plate and a metal hollow tube having a metal tubular wall, the metal plate including a surface facing the thermal insulating plate; and
a second plurality of reduced contact features formed on the surface of the metal plate, the thermal insulating plate being in contact with the second plurality of reduced contact features.

8. The substrate support assembly of claim 7, wherein the heater plate is fabricated from a ceramic material.

9. The substrate support assembly of claim 8, wherein the thermal insulating plate is fabricated from a ceramic material.

10. The substrate support assembly of claim 9, wherein the thermal insulating plate is fabricated from aluminum oxide or aluminum nitride.

11. The substrate support assembly of claim 7, wherein the metal shield is fabricated from aluminum.

12. The substrate support assembly of claim 7, further comprising a coolant channel formed in the metal plate and the tubular wall of the metal hollow tube, wherein the coolant channel comprises:
a supply channel having a planar spiral pattern in the metal plate and a helical pattern in the tubular wall of the metal hollow tube; and
a return channel having a planar spiral pattern in the metal plate and a helical pattern in the tubular wall of the metal hollow tube, the supply channel and the return channel being interleaved in the metal plate and the tubular wall.

13. A process chamber, comprising:
a chamber wall;
a bottom;
a gas distribution plate; and
a substrate support assembly, comprising:
a heater plate;
a thermal insulating plate having a surface facing the heater plate;
a first plurality of reduced contact features formed on the surface of the thermal insulating plate, the heater plate being in contact with the first plurality of reduced contact features;
a metal shield comprising a metal plate and a metal hollow tube having a metal tubular wall, the metal plate including a surface facing the thermal insulating plate; and
a second plurality of reduced contact features formed on the surface of the metal plate, the thermal insulating plate being in contact with the second plurality of reduced contact features.

14. The process chamber of claim 13, wherein the heater plate is fabricated from a ceramic material.

15. The process chamber of claim 14, further comprising a heating element embedded in the heater plate.

16. The process chamber of claim 13, wherein the thermal insulating plate is fabricated from a ceramic material.

17. The process chamber of claim 13, wherein the thermal insulating plate is fabricated from aluminum oxide or aluminum nitride.

18. The process chamber of claim 13, wherein the metal shield is fabricated from aluminum.

19. The process chamber of claim 13, wherein the second plurality of reduced contact features comprises a plurality of sapphire balls partially embedded in the metal plate.

20. The process chamber of claim 13, further comprising a coolant channel formed in the metal plate and the tubular wall of the metal hollow tube, wherein the coolant channel comprises:
a supply channel having a planar spiral pattern in the metal plate and a helical pattern in the tubular wall of the metal hollow tube; and
a return channel having a planar spiral pattern in the metal plate and a helical pattern in the tubular wall of the metal hollow tube, the supply channel and the return channel being interleaved in the metal plate and the tubular wall.
